(19) United States
(12) Patent Application Publication
(10) Pub. No.: US 2025/0267938 A1
(43) Pub. Date: Aug. 21, 2025

(54) SEMICONDUCTOR INTEGRATED CIRCUIT DEVICE

(71) Applicant: Socionext Inc., Kanagawa (JP)

(72) Inventor: Masachika ONO, Yokohama-shi (JP)

(21) Appl. No.: 19/187,256

(22) Filed: Apr. 23, 2025

Related U.S. Application Data
(63) Continuation of application No. PCT/JP2023/041091, filed on Nov. 15, 2023.

(30) Foreign Application Priority Data
Nov. 29, 2022 (JP) 2022-190002

(51) Int. Cl. H10D 84/90; H10D 89/10

(52) U.S. Cl. CPC H10D 84/981; H10D 84/953; H10D 89/10

(57) ABSTRACT

A standard cell is formed between first and second power lines, lying astride a third power line. The spacing between the first and third power lines is greater than the spacing between the second and third power lines. The standard cell has a first logic circuit that receives an input A and outputs a signal to an internal node and a second logic circuit that receives the signal from the internal node and outputs an output Y. Transistors constituting the first logic circuit are formed in a region between the second and third power lines, and transistors constituting the second logic circuit are formed in a region between the first and third power lines.

### CROSS-REFERENCE TO RELATED APPLICATIONS

This is a continuation of International Application No. PCT/JP2023/041091 filed on Nov. 15, 2023, which claims priority to Japanese Patent Application No. 2022-190002 filed on Nov. 29, 2022. The entire disclosures of these applications are incorporated by reference herein.

### BACKGROUND

The present disclosure relates to a semiconductor integrated circuit device.

As a method for forming a semiconductor integrated circuit on a semiconductor substrate, a standard cell method is known. The standard cell method is a method in which basic units (e.g., inverters, latches, flipflops, and full adders) having specific logical functions are prepared in advance as standard cells, and a plurality of such standard cells are placed on a semiconductor substrate and connected through interconnects, whereby an LSI chip is designed.

Also, as for a transistor, which is a basic constituent of an LSI, improvement in integration degree, reduction in operating voltage, and improvement in operating speed have been achieved by reducing (scaling) the gate length. In recent years, however, increase in off current due to excessive scaling and the resulting significant increase in power consumption have raised a problem. To solve this problem, three-dimensional transistors, of which the transistor structure has changed from the conventional planar structure to a three-dimensional structure, have been vigorously studied. A nanosheet FET is one example of such three-dimensional transistors.

US Patent Application Publication No. 2022/0262786 discloses a semiconductor integrated circuit device in which standard cell rows different in height are arranged alternately and some standard cells lie astride a plurality of standard cell rows.

The cited patent document describes optimizing the performance of standard cells lying astride a plurality of standard cell rows different in height. However, the cited patent document has not disclosed a specific layout structure of such standard cells.

An objective of the present disclosure is presenting a layout structure of a standard cell lying astride a plurality of standard cell rows different in height.

### SUMMARY

According to the first mode of the disclosure, a semiconductor integrated circuit device includes: a first power line extending in a first direction and supplying a first power supply voltage; a second power line extending in the first direction and supplying the first power supply voltage; a third power line extending in the first direction between the first power line and the second power line, and supplying a second power supply voltage different from the first power supply voltage; and a standard cell formed between the first power line and the second power line, wherein the spacing between the first power line and the third power line is greater than the spacing between the second power line and the third power line, the standard cell includes a first logic circuit configured to receive an input signal from an input terminal and output a signal to an internal node, and a second logic circuit configured to receive the signal from the internal node and output an output signal to an output terminal, a first transistor constituting the first logic circuit is formed in a region between the second power line and the third power line, and a second transistor constituting the second logic circuit is formed in a region between the first power line and the third power line.

According to the above mode, the standard cell is formed between the first power line and the second power line, lying astride the third power line. The spacing between the first and third power lines is greater than the spacing between the second and third power lines. The standard cell has a first logic circuit that receives an input signal and outputs a signal to an internal node and a second logic circuit that receives the signal from the internal node and outputs an output signal. First transistors constituting the first logic circuit are formed in a region between the second and third power lines, and second transistors constituting the second logic circuit are formed in a region between the first and third power lines. Therefore, the channel width of the second transistors can be made greater than the channel width of the first transistors. In this way, a circuit small in input capacity and high in output drive capability can be implemented with a small area.

According to the second mode of the disclosure, a semiconductor integrated circuit device includes: a first power line extending in a first direction and supplying a first power supply voltage; a second power line extending in the first direction and supplying the first power supply voltage; a third power line extending in the first direction between the first power line and the second power line, and supplying a second power supply voltage different from the first power supply voltage; and a standard cell formed between the first power line and the second power line, wherein the spacing between the first power line and the third power line is greater than the spacing between the second power line and the third power line, the standard cell includes a first logic circuit configured to receive an input signal from an input terminal and output a signal to an internal node, and a second logic circuit configured to receive the signal from the internal node and output an output signal to an output terminal, a first transistor constituting the first logic circuit is formed in a region between the first power line and the third power line, and a second transistor constituting the second logic circuit is formed in a region between the second power line and the third power line.

According to the above mode, the standard cell is formed between the first and second power lines, lying astride the third power line. The spacing between the first and third power lines is greater than the spacing between the second and third power lines. The standard cell has a first logic circuit that receives an input signal and outputs a signal to an internal node and a second logic circuit that receives the signal from the internal node and outputs an output signal. First transistors constituting the first logic circuit are formed in a region between the first and third power lines, and second transistors constituting the second logic circuit are formed in a region between the second and third power lines. Therefore, the channel width of the second transistors can be made smaller than the channel width of the first transistors. Thus, since the output drive capability of the first logic circuit is great and the input capacity of the second logic circuit is small, the delay inside the standard cell can be reduced.

According to the present disclosure, a small-area, high-speed semiconductor integrated circuit device can be implemented using a standard cell lying astride a plurality of standard cell rows different in height.

### BRIEF DESCRIPTION OF THE DRAWINGS

FIG. 1 shows an example of a block layout of a semiconductor integrated circuit device according to an embodiment.

FIGS. 2A and 2B are plan views showing layout structure examples of single-height cells.

FIG. 3 is a circuit diagram of a buffer circuit.

FIG. 4 is a plan view showing a layout structure example of a double-height cell according to the first embodiment.

FIGS. 5A and 5B are cross-sectional views of the layout structure of FIG. 4.

FIG. 6 is a plan view showing a layout structure example of a double-height cell according to the first embodiment.

FIG. 7 is a plan view showing a layout structure example of a double-height cell according to the first embodiment.

FIG. 8 is a circuit diagram of a 2-input AND circuit.

FIG. 9 is a plan view showing a layout structure example of a double-height cell according to the first embodiment.

FIG. 10 is a circuit diagram of a 2-input OR circuit.

FIG. 11 is a plan view showing a layout structure example of a double-height cell according to the first embodiment.

FIG. 12 is a circuit diagram of a 4-input AND circuit.

FIG. 13 is a plan view showing a layout structure example of a double-height cell according to the first embodiment.

FIG. 14 is a plan view showing a layout structure example of a double-height cell according to the second embodiment.

FIG. 15 is a plan view showing a layout structure example of a double-height cell according to the second embodiment.

FIG. 16 is a plan view showing a layout structure example of a double-height cell according to the second embodiment.

### DETAILED DESCRIPTION

Embodiments of the present disclosure will be described hereinafter with reference to the accompanying drawings. In the following embodiments, it is assumed that the semiconductor integrated circuit device includes a plurality of standard cells (hereinafter simply called cells as appropriate), and at least some of the standard cells include nanosheet field effect transistors (FETs). The nanosheet FET is a FET using a thin sheet (nanosheet) through which a current flows. Such a nanosheet is formed of silicon, for example.

As used herein, “VDD” and “VSS” refer to the power supply voltages or the power supplies themselves. Also, as used herein, an expression indicating that sizes such as widths are identical, like the “same wiring width,” is to be understood as including a range of manufacturing variations.

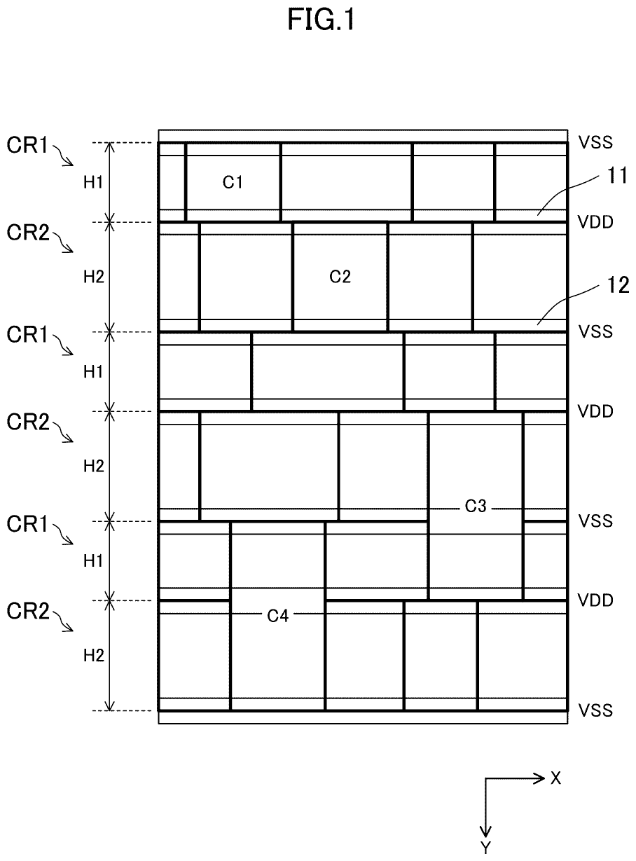

Note that, in the plan views such as FIG. 1, the horizontal direction in the figure is hereinafter referred to as an X direction (corresponding to the first direction), the vertical direction in the figure as a Y direction (corresponding to the second direction), and the direction perpendicular to the substrate plane as a Z direction.

### First Embodiment

FIG. 1 shows an example of a block layout of a semiconductor integrated circuit device according to an embodiment. The block layout of FIG. 1 is configured by placing standard cells. In FIG. 1, only the cell frames of standard cells and power lines are illustrated, omitting the internal structures of the standard cells and interconnects between the standard cells.

In the block layout of FIG. 1, power lines 11 supplying the power supply voltage VDD and power lines 12 supplying the power supply voltage VSS are laid alternately in the Y direction. Cells are arranged in line in the X direction between the power lines 11 and the power lines 12, forming cell rows CR1 and CR2. Each of the power lines 11 and 12 is shared by the cell rows CR1 and CR2 formed immediately above and below the power line in the figure.

The height of the cell rows CR1 is H1 and the height of the cell rows CR2 is H2, where the height H2 is greater than the height H1 (H2>H1). The cell rows CR1 and the cell rows CR2 are arranged alternately in the Y direction.

Cells C1 and C2 are single-height cells. The cell C1, placed in the cell row CR1, has the height H1, and the cell C2, placed in the cell row CR2, has the height H2. Cells C3 and C4 are double-height cells. The cells C3 and C4, placed astride the cell rows CR1 and CR2, have a height (H1+H2). In the cell C3, the power line 12 supplying VSS runs across the center portion. In the cell C4, the power line 11 supplying VDD runs across the center portion.

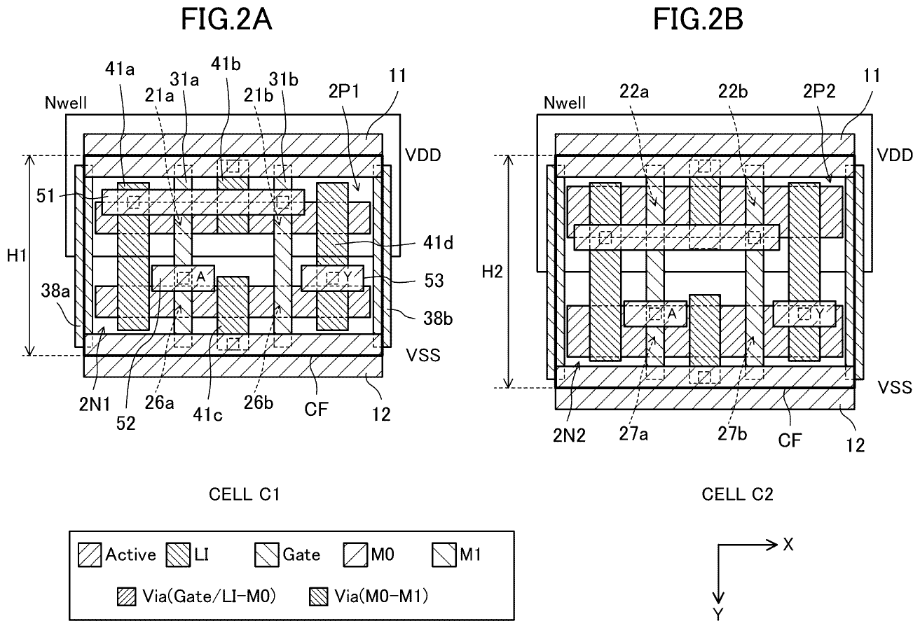

FIGS. 2A-2B are plan views showing layout structure examples of single-height cells in the block layout of FIG. 1, where FIG. 2A shows the cell C1 and FIG. 2B shows the cell C2. Note that, in the block layout of FIG. 1, the cell C1 of FIG. 2A is placed in a vertically flipped position. The power lines 11 and 12 are formed in an M0 interconnect layer that is a metal interconnect layer. CF denotes the cell frame.

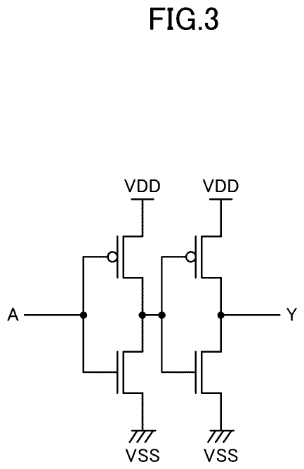

FIG. 3 is a circuit diagram of the single-height cells of FIGS. 2A and 2B. As shown in FIG. 3, the cells C1 and C2 of FIGS. 2A and 2B are each constituted by two-staged inverters, forming a buffer circuit having an input A and an output Y.

In the cell C1 shown in FIG. 2A, an active region 2P1 forming the channels, sources, and drains of p-type transistors is formed in a p-type transistor region on an n-type well (NWell). The active region 2P1 includes nanosheets 21a and 21b each having a structure of three sheets lying one above another and extending in the X direction. An active region 2N1 forming the channels, sources, and drains of n-type transistors is formed in an n-type transistor region on a p-type substrate. The active region 2N1 includes nanosheets 26a and 26b each having a structure of three sheets lying one above another and extending in the X direction. Note that, in the active regions, the portions that are to be the sources and the drains on both sides of the nanosheets are formed by epitaxial growth from the nanosheets. Note also that the active region of the n-type transistors may be formed on a p-type well, not on the p-type substrate.

Gate interconnects 31a and 31b extending in parallel in the Y direction are formed from the p-type transistor region over to the n-type transistor region. Also, dummy gate interconnects 38a and 38b are formed on the side portions of the cell frame CF in the X direction. The dummy gate interconnect 38a is shared with a cell placed on the left in the figure, and the dummy gate interconnect 38b is shared with a cell placed on the right in the figure. The gate interconnects 31a and 31b and the dummy gate interconnects 38a and 38b have the same width and are placed at the same pitch.

The gate interconnect 31a surrounds the peripheries of the nanosheets 21a included in the active region 2P1 in the Y and Z directions via gate insulating films (not shown). Also, the gate interconnect 31a surrounds the peripheries of the nanosheets 26a included in the active region 2N1 in the Y and Z directions via gate insulating films (not shown). The gate interconnect 31b surrounds the peripheries of the nanosheets 21b included in the active region 2P1 in the Y and Z directions via gate insulating films (not shown). Also, the gate interconnect 31b surrounds the peripheries of the nanosheets 26b included in the active region 2N1 in the Y and Z directions via gate insulating films (not shown).

Local interconnects 41a, 41b, 41c, and 41d (abbreviated as LI in the figures) extending in the Y direction are formed in a local interconnect layer. The local interconnects 41a and 41d extend from the p-type transistor region over to the n-type transistor region. The local interconnect 41a is connected to the portions that are to be the sources or the drains located on the left of the gate interconnect 31a in the figure in the active regions 2P1 and 2N1. The local interconnect 41b is connected to the portion that is to be the source or the drain located between the gate interconnects 31a and 31b in the active region 2P1. The local interconnect 41c is connected to the portion that is to be the source or the drain located between the gate interconnects 31a and 31b in the active region 2N1. The local interconnect 41d is connected to the portions that are to be the sources or the drains located on the right of the gate interconnect 31b in the figure in the active regions 2P1 and 2N1.

Metal interconnects 51, 52, and 53 extending in the X direction are formed in the M0 interconnect layer in which the power lines 11 and 12 are also formed. The metal interconnect 51 is connected to the local interconnect 41a through a via, and also connected to the gate interconnect 31b through a via. The metal interconnect 52 is connected to the gate interconnect 31a through a via. The metal interconnect 52 corresponds to the input A of the buffer circuit. The metal interconnect 53 is connected to the local interconnect 41d through a via. The metal interconnect 53 corresponds to the output Y of the buffer circuit.

The layout structure of the cell C2 shown in FIG. 2B is basically the same as that of the cell C1 shown in FIG. 2A. However, since the height H2 of the cell C2 is greater than the height H1 of the cell C1 (H2>H1), the size of active regions 2P2 and 2N2 in the Y direction in the cell C2 is greater than the size of the active regions 2P1 and 2N1 in the Y direction in the cell C1. That is, the width of nanosheets 22a and 22b and nanosheets 27a and 27b in the cell C2 is greater than the width of the nanosheets 21a and 21b and the nanosheets 26a and 26b in the cell C1 (note that the width of nanosheets herein refers to the width or the size in the Y direction in the figure). Therefore, the output drive capability of the cell C2 is greater than the output drive capability of the cell C1. Also, the input capacity of the cell C2 is greater than the input capacity of the cell C1.

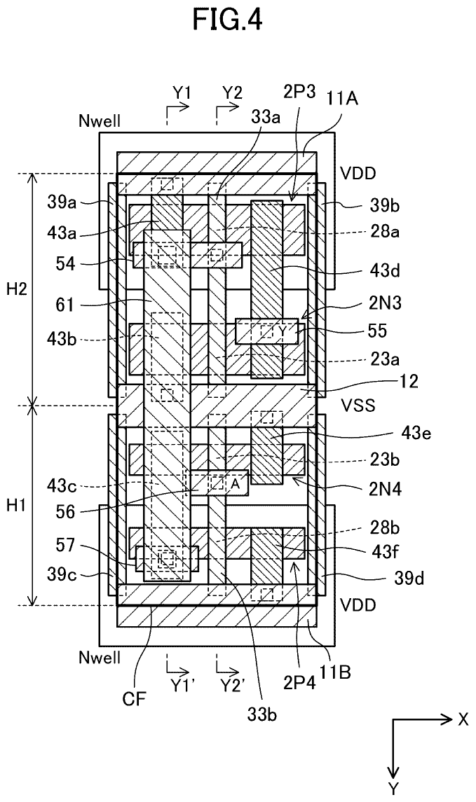

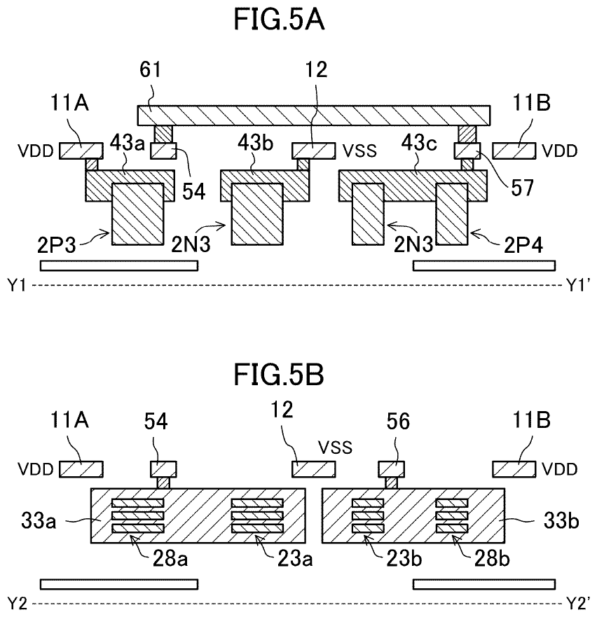

FIG. 4 is a plan view showing a layout structure example of the double-height cell C3 in the block layout of FIG. 1. FIGS. 5A and 5B are cross-sectional views of the layout structure of FIG. 4, where FIG. 5A is a cross section taken along line Y1-Y1′ and FIG. 5B is a cross section taken along line Y2-Y2′. The circuit structure of the cell C3 of FIGS. 4, 5A, and 5B is as shown in FIG. 3, that is, constituted by two-staged inverters, forming a buffer circuit having an input A and an output Y. The input-side inverter corresponds to the first logic circuit according to the present disclosure, and the output-side inverter corresponds to the second logic circuit according to the present disclosure.

As shown in FIG. 4, in the cell C3, the power line 12 supplying VSS is laid in the center portion in the Y direction. Also, power lines 11A and 11B supplying VDD are laid in both end portions in the Y direction. In the region between the power lines 11A and 12, having the height H2, transistors constituting the output-side inverter of the buffer circuit are formed. In the region between the power lines 11B and 12, having the height H1, transistors constituting the input-side inverter of the buffer circuit are formed.

An active region 2N3 forming the channel, source, and drain of an n-type transistor is formed in an n-type transistor region on the upper side of the power line 12 in the figure. The active region 2N3 includes nanosheets 23a having a structure of three sheets lying one above another and extending in the X direction. An active region 2N4 forming the channel, source, and drain of an n-type transistor is formed in an n-type transistor region on the lower side of the power line 12 in the figure. The active region 2N4 includes nanosheets 23b having a structure of three sheets lying one above another and extending in the X direction.

An active region 2P3 forming the channel, source, and drain of a p-type transistor is formed in a p-type transistor region on the lower side of the power line 11A, which is laid in the upper end portion, in the figure. The active region 2P3 includes nanosheets 28a having a structure of three sheets lying one above another and extending in the X direction. An active region 2P4 forming the channel, source, and drain of a p-type transistor is formed in a p-type transistor region on the upper side of the power line 11B, which is laid in the lower end portion, in the figure. The active region 2P4 includes nanosheets 28b having a structure of three sheets lying one above another and extending in the X direction.

A gate interconnect 33a extending in the Y direction is formed in the region between the power lines 11A and 12, and dummy gate interconnects 39a and 39b are formed on the side portions of the cell frame CF in the X direction. The dummy gate interconnect 39a is shared with a cell placed on the left in the figure, and the dummy gate interconnect 39b is shared with a cell placed on the right in the figure. The gate interconnect 33a and the dummy gate interconnects 39a and 39b have the same width and are placed at the same pitch.

The gate interconnect 33a surrounds the peripheries of the nanosheets 28a included in the active region 2P3 in the Y and Z directions via gate insulating films (not shown). Also, the gate interconnect 33a surrounds the peripheries of the nanosheets 23a included in the active region 2N3 in the Y and Z directions via gate insulating films (not shown).

A gate interconnect 33b extending in the Y direction is formed in the region between the power lines 11B and 12, and dummy gate interconnects 39c and 39d are formed on the side portions of the cell frame CF in the X direction. The dummy gate interconnect 39c is shared with a cell placed on the left in the figure, and the dummy gate interconnect 39d is shared with a cell placed on the right in the figure. The gate interconnect 33b and the dummy gate interconnects 39c and 39d have the same width and are placed at the same pitch.

The gate interconnect 33b surrounds the peripheries of the nanosheets 28b included in the active region 2P4 in the Y and Z directions via gate insulating films (not shown). Also, the gate interconnect 33b surrounds the peripheries of the nanosheets 23b included in the active region 2N4 in the Y and Z directions via gate insulating films (not shown).

Local interconnects 43a, 43b, 43c, 43d, 43e, and 43f extending in the Y direction are formed in a local interconnect layer. The local interconnect 43a is connected to the portion that is to be the source or the drain located on the left of the gate interconnect 33a in the figure in the active region 2P3, and also connected to the power line 11A through a via. The local interconnect 43b is connected to the portion that is to be the source or the drain located on the left of the gate interconnect 33a in the figure in the active region 2N3, and also connected to the power line 12 through a via. The local interconnect 43c is connected to the portions that are to be the sources or the drains located on the left of the gate interconnect 33b in the figure in the active regions 2N4 and 2P4.

The local interconnect 43d is connected to the portions that are to be the sources or the drains located on the right of the gate interconnect 33a in the figure in the active regions 2N3 and 2P3. The local interconnect 43e is connected to the portion that is to be the source or the drain located on the right of the gate interconnect 33b in the figure in the active region 2N4, and also connected to the power line 12 through a via. The local interconnect 43f is connected to the portion that is to be the source or the drain located on the right of the gate interconnect 33b in the figure in the active region 2P4, and also connected to the power line 11B through a via

Metal interconnects 54, 55, 56, and 57 extending in the X direction are formed in an M0 interconnect layer in which the power lines 11A, 11B, and 12 are also formed. The metal interconnect 54 is connected to the gate interconnect 33a through a via. The metal interconnect 55 is connected to the local interconnect 43d through a via, and corresponds to the output terminal Y of the buffer circuit. The metal interconnect 56 is connected to the gate interconnect 33b through a via, and corresponds to the input terminal A of the buffer circuit. The metal interconnect 57 is connected to the local interconnect 43c through a via.

A metal interconnect 61 extending in the Y direction is formed in an M1 interconnect layer that is a metal interconnect layer located above the M0 interconnect layer. The metal interconnect 61 is connected to the metal interconnects 54 and 57 through vias, and corresponds to the inner node of the buffer circuit.

In the double-height cell C3 shown in FIGS. 4, 5A, and 5B, the height H2 of the region between the power lines 11A and 12 is greater than the height H1 of the region between the power lines 11B and 12 (H2>H1). Therefore, the size of the active regions 2P3 and 2N3 in the Y direction is greater than the size of the active regions 2P4 and 2N4 in the Y direction. That is, the width of the nanosheets 23a and 28a of the transistors constituting the output-side inverter is greater than the width of the nanosheets 23b and 28b of the transistors constituting the input-side inverter. The cell C3 can therefore implement a buffer circuit small in input capacity (equivalent to that of the cell C1) and high in output drive capability (equivalent to that of the cell C2) with a small area. As a result, a high-speed, small-area semiconductor integrated circuit device can be implemented. This is particularly effective when the output drive capability of a cell connected to the input A of the cell C3 is small and when the load capacity due to a cell or cells and interconnects connected to the output Y is large.

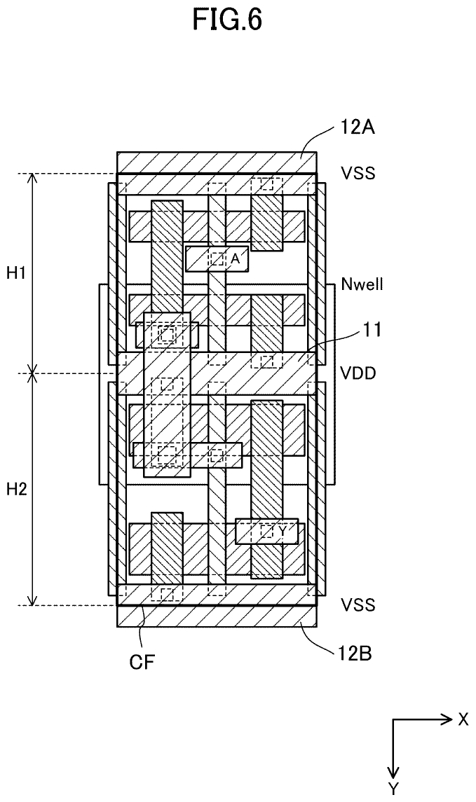

FIG. 6 is a plan view showing a layout structure example of the double-height cell C4 in the block layout of FIG. 1. The circuit structure of the cell C4 of FIG. 6 is as shown in FIG. 3, that is, constituted by two-staged inverters, forming a buffer circuit having an input A and an output Y.

As shown in FIG. 6, in the cell C4, the power line 11 supplying VDD is laid in the center portion in the Y direction. Also, power lines 12A and 12B supplying VSS are laid in both end portions in the Y direction. In the region between the power lines 11 and 12A, having the height H1, transistors constituting the input-side inverter of the buffer circuit are formed. In the region between the power lines 11 and 12B, having the height H2, transistors constituting the output-side inverter of the buffer circuit are formed.

Since the layout structure of the cell C4 of FIG. 6 can be easily known by analogy from the layout structure of the cell C3 shown in FIGS. 4, 5A, and 5B, detailed description is omitted here.

The double-height cell C4 of FIG. 6 can obtain similar effects to those obtained by the double-height cell C3 shown in FIGS. 4, 5A, and 5B. That is, the height H2 of the region between the power lines 11 and 12B is greater than the height H1 of the region between the power lines 11 and 12A (H2>H1). Therefore, the width of the nanosheets of the transistors constituting the output-side inverter is greater than the width of the nanosheets of the transistors constituting the input-side inverter. The cell C4 can therefore implement a buffer circuit small in input capacity (equivalent to that of the cell C1) and high in output drive capability (equivalent to that of the cell C2) with a small area. As a result, a high-speed, small-area semiconductor integrated circuit device can be implemented. This is particularly effective when the output drive capability of a cell connected to the input A of the cell C4 is small and when the load capacity due to a cell or cells and interconnects connected to the output Y is large.

### <Other Layout Structure Examples>

Other layout structure examples of the double-height cell C3 according to this embodiment will be described. Note that, in the following examples, the layout structure shown in FIGS. 4, 5A, and 5B is used as the basic configuration, and description may be omitted for configurations that can be easily known by analogy from the above description.

### (1) 2-Input AND Circuit

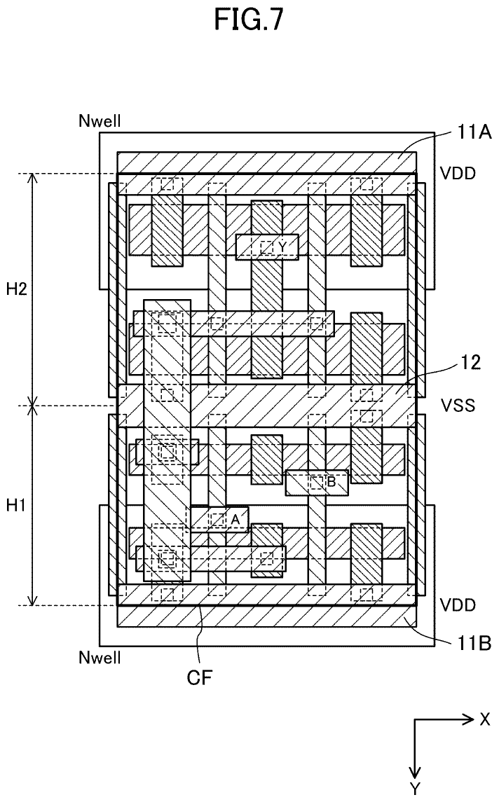

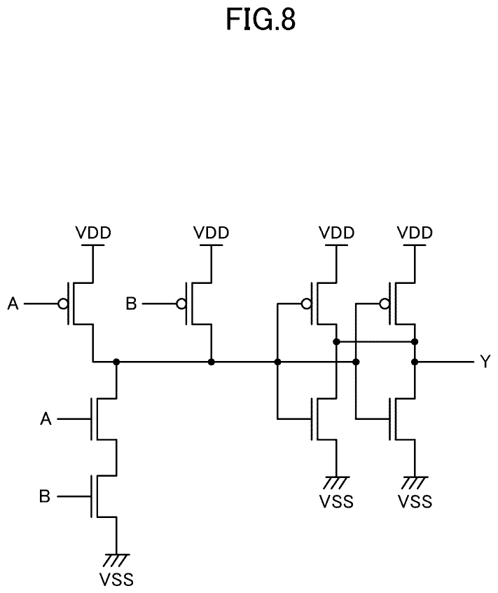

FIG. 7 is a plan view showing another layout structure of the double-height cell C3. The layout structure of FIG. 7 has a cell width 3/2 times that of FIG. 4. The cell C3 shown in FIG. 7 implements a 2-input AND circuit shown in FIG. 8. The 2-input AND circuit shown in FIG. 8 includes a NAND gate at the first stage and an inverter at the second stage. The second-stage inverter is constituted by two inverters connected in parallel. The first-stage NAND gate corresponds to the first logic circuit according to the present disclosure, and the second-stage inverter corresponds to the second logic circuit according to the present disclosure.

As shown in FIG. 7, in the cell C3, the power line 12 supplying VSS is laid in the center portion in the Y direction. Also, the power lines 11A and 11B supplying VDD are laid in both end portions in the Y direction. In the region between the power lines 11A and 12, having the height H2, transistors constituting the second-stage inverter of the 2-input AND circuit are formed. In the region between the power lines 11B and 12, having the height H1, transistors constituting the first-stage NAND gate of the 2-input AND circuit are formed.

In the double-height cell C3 of FIG. 7, the width of the nanosheets of the transistors constituting the second-stage inverter is greater than the width of the nanosheets of the transistors constituting the first-stage NAND gate. Therefore, the cell C3 can implement a 2-input AND circuit small in input capacity (equivalent to that of the cell C1) and high in output drive capability (equivalent to double that of the cell C2 because two inverters are connected in parallel) with a small area.

### (2) 2-Input OR Circuit

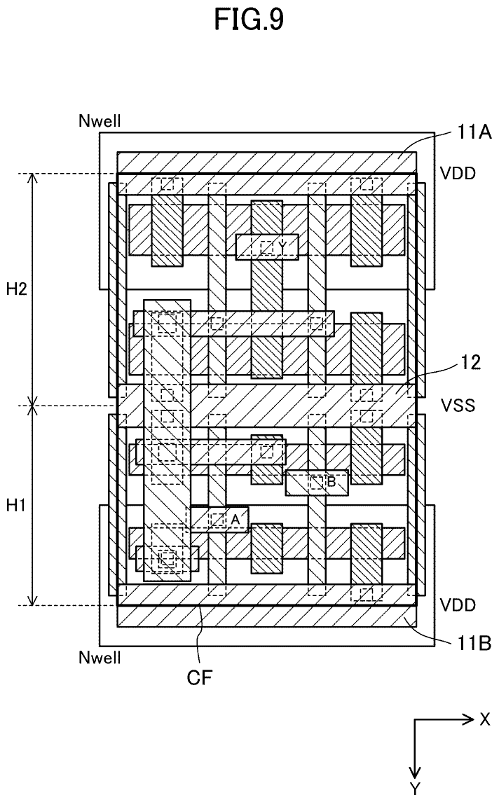

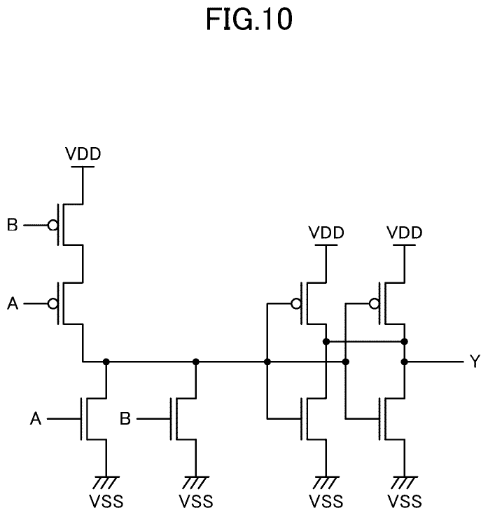

FIG. 9 is a plan view showing yet another layout structure of the double-height cell C3. The layout structure of FIG. 9 has a cell width 3/2 times that of FIG. 4. The cell C3 shown in FIG. 9 implements a 2-input OR circuit shown in FIG. 10. The 2-input OR circuit shown in FIG. 10 includes a NOR gate at the first stage and an inverter at the second stage. The second-stage inverter is constituted by two inverters connected in parallel. The first-stage NOR gate corresponds to the first logic circuit according to the present disclosure, and the second-stage inverter corresponds to the second logic circuit according to the present disclosure.

As shown in FIG. 9, in the cell C3, the power line 12 supplying VSS is laid in the center portion in the Y direction. Also, the power lines 11A and 11B supplying VDD are laid in both end portions in the Y direction. In the region between the power lines 11A and 12, having the height H2, transistors constituting the second-stage inverter of the 2-input OR circuit are formed. In the region between the power lines 11B and 12, having the height H1, transistors constituting the first-stage NOR gate of the 2-input OR circuit are formed.

In the double-height cell C3 of FIG. 9, the width of the nanosheets of the transistors constituting the second-stage inverter is greater than the width of the nanosheets of the transistors constituting the first-stage NOR gate. Therefore, the cell C3 can implement a 2-input OR circuit small in input capacity (equivalent to that of the cell C1) and high in output drive capability (equivalent to double that of the cell C2 because two inverters are connected in parallel) with a small area.

### (3) 4-Input AND Circuit

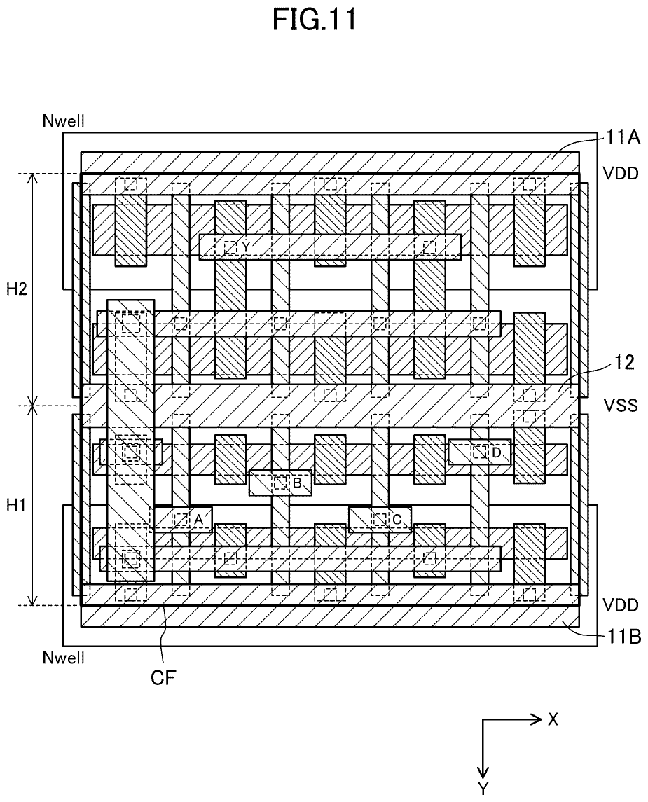

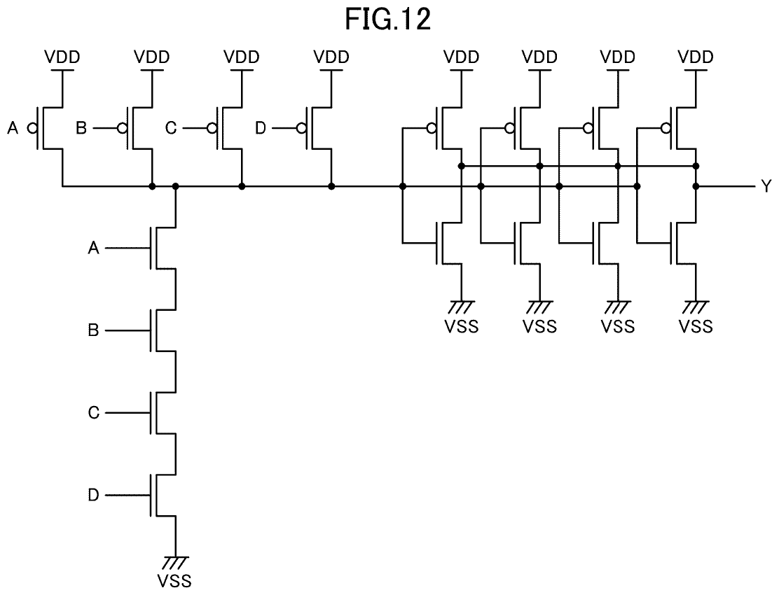

FIG. 11 is a plan view showing yet another layout structure of the double-height cell C3. The layout structure of FIG. 11 has a cell width 5/2 times that of FIG. 4. The cell C3 shown in FIG. 11 implements a 4-input AND circuit shown in FIG. 12. The 4-input AND circuit shown in FIG. 12 includes a 4-input NAND gate at the first stage and an inverter at the second stage. The second-stage inverter is constituted by four inverters connected in parallel. The first-stage 4-input NAND gate corresponds to the first logic circuit according to the present disclosure, and the second-stage inverter corresponds to the second logic circuit according to the present disclosure.

As shown in FIG. 11, in the cell C3, the power line 12 supplying VSS is laid in the center portion in the Y direction. Also, the power lines 11A and 11B supplying VDD are laid in both end portions in the Y direction. In the region between the power lines 11A and 12, having the height H2, transistors constituting the second-stage inverter of the 4-input AND circuit are formed. In the region between the power lines 11B and 12, having the height H1, transistors constituting the first-stage 4-input NAND gate of the 4-input AND circuit are formed.

In the double-height cell C3 of FIG. 11, the width of the nanosheets of the transistors constituting the second-stage inverter is greater than the width of the nanosheets of the transistors constituting the first-stage NAND gate. Therefore, the cell C3 can implement a 4-input AND circuit small in input capacity (equivalent to that of the cell C1) and high in output drive capability (equivalent to four times that of the cell C2 because four inverters are connected in parallel) with a small area.

### (4) Another 4-Input AND Circuit

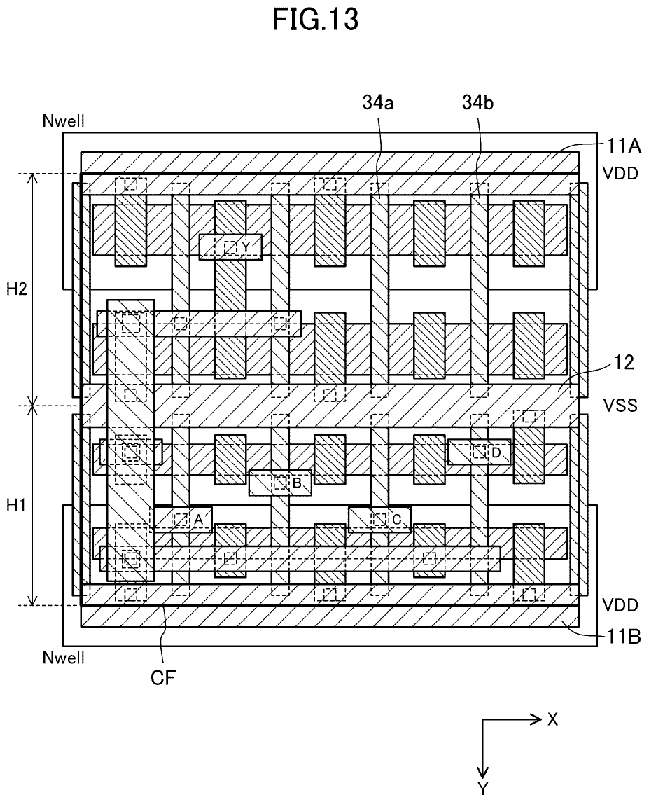

FIG. 13 is a plan view showing yet another layout structure of the double-height cell C3. The layout structure of FIG. 13 has a cell width 5/2 times that of FIG. 4. The cell C3 shown in FIG. 13 implements a 4-input AND circuit, like the layout structure of FIG. 11. In FIG. 13, however, the second-stage inverter is constituted by two inverters connected in parallel, not four inverters connected in parallel.

As shown in FIG. 13, in the cell C3, the power line 12 supplying VSS is laid in the center portion in the Y direction. Also, the power lines 11A and 11B supplying VDD are laid in both end portions in the Y direction. In the region between the power lines 11A and 12, having the height H2, transistors constituting the second-stage inverter of the 4-input AND circuit are formed. Note here that transistors constituted by gate interconnects 34a and 34b are dummy transistors that do not contribute to circuit operation. That is, the cell C3 of FIG. 13 includes dummy transistors. In the region between the power lines 11B and 12, having the height H1, transistors constituting the first-stage NAND gate of the 4-input AND circuit are formed.

In the double-height cell C3 of FIG. 13, the width of the nanosheets of the transistors constituting the second-stage inverter is greater than the width of the nanosheets of the transistors constituting the first-stage NAND gate. Therefore, the cell C3 can implement a 4-input AND circuit small in input capacity (equivalent to that of the cell C1) and high in output drive capability (equivalent to double that of the cell C2 because two inverters are connected in parallel) with a small area.

### Second Embodiment

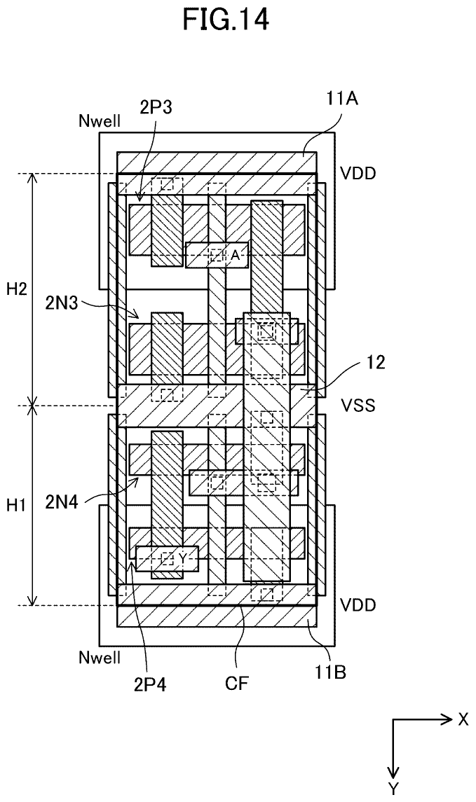

FIG. 14 is a plan view showing a layout structure example of the double-height cell C3 according to the second embodiment. The circuit structure of the cell C3 of FIG. 14 is as shown in FIG. 3, that is, constituted by two-staged inverters, forming a buffer circuit having an input A and an output Y.

In the layout structure of FIG. 14, in comparison with the layout structure of FIG. 4, the positions of the input-side inverter and the output-side inverter are changed with each other vertically in the figure. That is, in FIG. 14, transistors constituting the input-side inverter of the buffer circuit are formed in the region between the power lines 11A and 12 having the height H2. Transistors constituting the output-side inverter of the buffer circuit are formed in the region between the power lines 11B and 12 having the height H1. Note that, since the layout structure of FIG. 14 can be easily known by analogy from the description in the first embodiment, detailed description is omitted here.

In the double-height cell C3 shown in FIG. 14, the height H2 of the region between the power lines 11A and 12 is greater than the height H1 of the region between the power lines 11B and 12 (H2>H1). Therefore, the size of active regions 2P3 and 2N3 in the Y direction is greater than the size of active regions 2P4 and 2N4 in the Y direction. That is, the width of the nanosheets of transistors constituting the input-side inverter is greater than the width of the nanosheets of transistors constituting the output-side inverter. Therefore, in the cell C3, while the input capacity is great (equivalent to that of the cell C2), the output drive capability of the input-side inverter is great. Also, the input capacity of the output-side inverter is small. As a result, the delay inside the cell from the input-side inverter to the output-side inverter becomes small.

Therefore, when the output drive capability of a cell connected to the input A is sufficiently great and the load capacity due to a cell or cells and interconnects connected to the output Y is small, a small-area, high-speed semiconductor integrated circuit device can be implemented.

### <Other Layout Structure Examples>

Other layout structure examples of the double-height cell C3 according to this embodiment will be described. Note that description may be omitted for configurations that can be easily known by analogy from the above description.

### (1) 2-Input AND Circuit

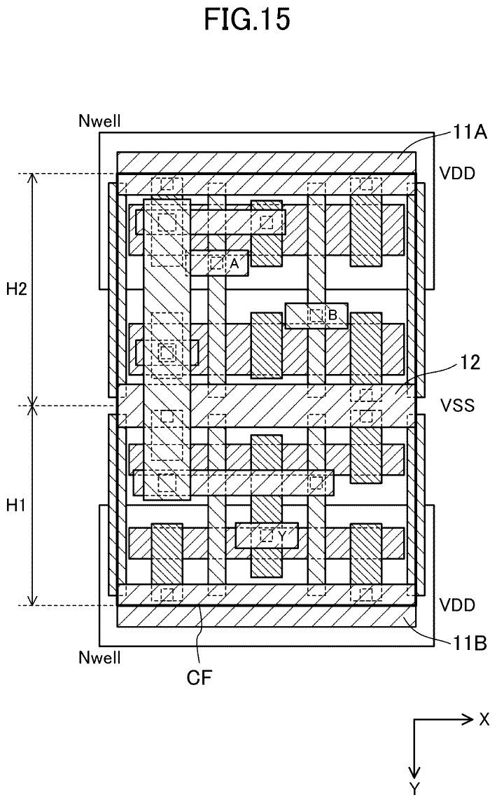

FIG. 15 is a plan view showing another layout structure of the double-height cell C3. The layout structure of FIG. 15 has a cell width 3/2 times that of FIG. 14. The cell C3 shown in FIG. 15 implements a 2-input AND circuit shown in FIG. 8.

In the layout structure of FIG. 15, in comparison with the layout structure of FIG. 7, the positions of the first-stage NAND gate and the second-stage inverter are changed with each other vertically in the figure. That is, transistors constituting the first-stage NAND gate of the 2-input AND circuit are formed in the region between the power lines 11A and 12 having the height H2. Transistors constituting the second-stage inverter of the 2-input AND circuit are formed in the region between the power lines 11B and 12 having the height H1.

In the double-height cell C3 of FIG. 15, the width of the nanosheets of transistors constituting the first-stage NAND gate is greater than the width of the nanosheets of transistors constituting the second-stage inverter. Therefore, in the cell C3, while the input capacity is great (equivalent to that of the cell C2), the output drive capability of the first-stage NAND gate is great. Also, the input capacity of the second-stage inverter is small. As a result, the delay inside the cell from the NAND gate to the inverter becomes small.

Therefore, when the output drive capabilities of cells connected to the inputs A and B are sufficiently great and the load capacity due to a cell or cells and interconnects connected to the output Y is small, a small-area, high-speed semiconductor integrated circuit device can be implemented.

### (2) 4-Input AND Circuit

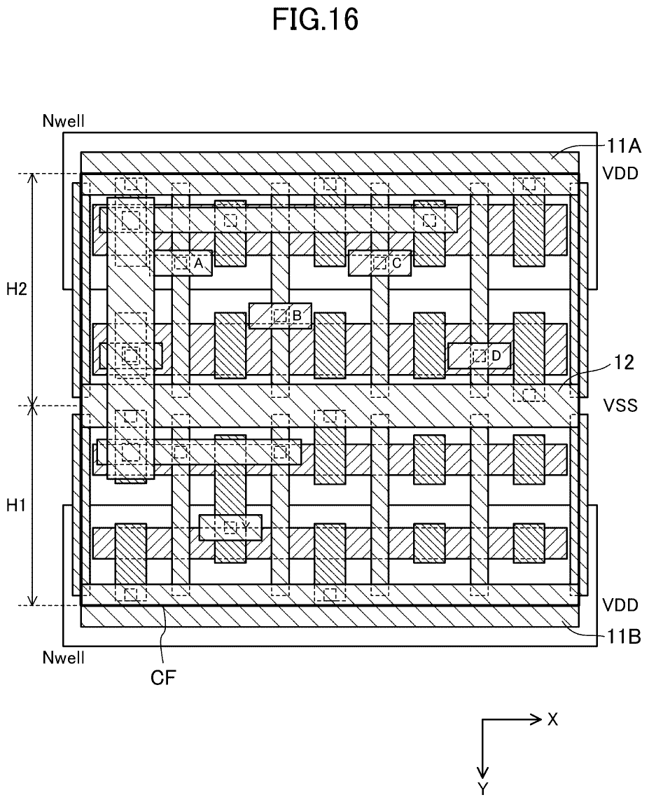

FIG. 16 is a plan view showing yet another layout structure of the double-height cell C3. The layout structure of FIG. 16 has a cell width 5/2 times that of FIG. 14. The cell C3 shown in FIG. 16 implements a 4-input AND circuit same in layout structure as that of FIG. 13.

In the layout structure of FIG. 16, in comparison with the layout structure of FIG. 13, the positions of the first-stage 4-input NAND gate and the second-stage inverter are changed with each other vertically in the figure. That is, transistors constituting the first-stage 4-input NAND gate of the 4-input AND circuit are formed in the region between the power lines 11A and 12 having the height H2. Transistors constituting the second-stage inverter of the 4-input AND circuit are formed in the region between the power lines 11B and 12 having the height H1.

In the double-height cell C3 of FIG. 16, the width of the nanosheets of transistors constituting the first-stage 4-input NAND gate is greater than the width of the nanosheets of transistors constituting the second-stage inverter. Therefore, in the cell C3, while the input capacity is great (equivalent to that of the cell C2), the output drive capability of the first-stage 4-input NAND gate is great. Also, the input capacity of the second-stage inverter is small. As a result, the delay inside the cell from the NAND gate to the inverter becomes small.

Therefore, when the output drive capabilities of cells connected to the inputs A, B, C, and D are sufficiently great and the load capacity due to a cell or cells and interconnects connected to the output Y is small, a small-area, high-speed semiconductor integrated circuit device can be implemented.

While the nanosheets have the structure of three sheets lying one above another and the cross-sectional shape of the sheet structure is illustrated as a rectangle in the above embodiments, the number of sheets, and the cross-sectional shape, of the structure of the nanosheets are not limited to these.

According to the present disclosure, the performance of a standard cell lying astride a plurality of standard cell rows different in height can be improved. The present disclosure is therefore useful for reduction in the area, and increase in the speed, of a semiconductor integrated circuit device, for example.

1. A semiconductor integrated circuit device, comprising:
a first power line extending in a first direction and supplying a first power supply voltage;
a second power line extending in the first direction and supplying the first power supply voltage;
a third power line extending in the first direction between the first power line and the second power line, and supplying a second power supply voltage different from the first power supply voltage; and
a standard cell formed between the first power line and the second power line, wherein
the spacing between the first power line and the third power line is greater than the spacing between the second power line and the third power line,
the standard cell includes
a first logic circuit configured to receive an input signal from an input terminal and output a signal to an internal node, and
a second logic circuit configured to receive the signal from the internal node and output an output signal to an output terminal,
a first transistor constituting the first logic circuit is formed in a region between the second power line and the third power line, and
a second transistor constituting the second logic circuit is formed in a region between the first power line and the third power line.

2. The semiconductor integrated circuit device of claim 1, wherein
the first and second transistors are nanosheet field effect transistors (FETs), and
the width of the nanosheet of the second transistor is greater than the width of the nanosheet of the first transistor.

3. The semiconductor integrated circuit device of claim 1, wherein
the standard cell includes
a dummy transistor that does not contribute to a logical function of the circuit.

4. A semiconductor integrated circuit device, comprising:
a first power line extending in a first direction and supplying a first power supply voltage;
a second power line extending in the first direction and supplying the first power supply voltage;
a third power line extending in the first direction between the first power line and the second power line, and supplying a second power supply voltage different from the first power supply voltage; and
a standard cell formed between the first power line and the second power line, wherein
the spacing between the first power line and the third power line is greater than the spacing between the second power line and the third power line,
the standard cell includes
a first logic circuit configured to receive an input signal from an input terminal and output a signal to an internal node, and
a second logic circuit configured to receive the signal from the internal node and output an output signal to an output terminal,
a first transistor constituting the first logic circuit is formed in a region between the first power line and the third power line, and
a second transistor constituting the second logic circuit is formed in a region between the second power line and the third power line.

5. The semiconductor integrated circuit device of claim 4, wherein
the first and second transistors are nanosheet field effect transistors (FETs), and
the width of the nanosheet of the second transistor is smaller than the width of the nanosheet of the first transistor.

6. The semiconductor integrated circuit device of claim 4, wherein
the standard cell includes
a dummy transistor that does not contribute to a logical function of the circuit.
